(19) United States
(12) Patent Application Publication
(10) Pub. No.: US 2020/0294855 A1
(43) Pub. Date: Sep. 17, 2020

(54) WAFER DICING WITH A FRAME FOR ENABLING A SHRINK

(71) Applicant: QUALCOMM Incorporated, San Diego, CA (US)

(72) Inventor: Markus VALTERE, Munich (DE)

(21) Appl. No.: 16/352,616

(22) Filed: Mar. 13, 2019

(51) Int. Cl. H01L 21/78; H01L 23/544; H01L 21/48; H01L 23/31

(52) U.S. Cl. CPC H01L 21/78; H01L 23/544; H01L 2223/54426; H01L 23/3171; H01L 21/4821

(57) ABSTRACT

Aspects of the disclosure are directed to wafer dicing with a frame. Accordingly, the dicing of the wafer includes forming a substrate layer in the wafer, wherein the substrate layer comprises a first substrate layer edge associated with the first device and a second substrate layer edge associated with the second device; depositing a passivation layer onto the substrate layer; and depositing a frame in the wafer, wherein the frame abuts the passivation layer and wherein the frame comprises a first frame edge associated with the first device and a second frame edge associated with the second device; and wherein a front width is a first distance between the first frame edge and the second frame edge, and a back width is a second distance between the first substrate layer edge and the second substrate layer edge; and wherein the front width is less than the back width.

### TECHNICAL FIELD

This disclosure relates generally to the field of wafer dicing, and, in particular, to wafer dicing with a frame.

### BACKGROUND

Production of devices, for example, semiconductor devices, may be facilitated using wafers (i.e., thin slivers of a semiconductor material) which include a plurality of devices (e.g., chips) on each wafer. In one example, the plurality of devices may be identical or significantly similar replicas of a common device design. For example, after device production, the wafer is diced (i.e., cut) or singulated into individual devices (e.g., chips) which are separately packaged. A quantity of devices per wafer is determined, for example, by a spacing (i.e., dicing lane (DL) width) between adjacent devices. What is desired is minimization (e.g., shrink of dicing lane width) of the spacing between adjacent devices (e.g., chips) on a wafer to increase the quantity of devices per wafer.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides wafer dicing with a frame. Accordingly, a method for dicing a wafer into a first device and a second device through a metal frame, the method including forming a substrate layer in the wafer, wherein the substrate layer comprises a first substrate layer edge associated with the first device and a second substrate layer edge associated with the second device; depositing a passivation layer onto the substrate layer; and depositing a frame in the wafer, wherein the frame abuts the passivation layer and wherein the frame comprises a first frame edge associated with the first device and a second frame edge associated with the second device; and wherein a front width is a first distance between the first frame edge and the second frame edge, and a back width is a second distance between the first substrate layer edge and the second substrate layer edge; and wherein the front width is less than the back width.

In one example, the method further includes dicing the wafer along a dicing lane to form the first device and the second device, wherein the dicing lane is within the first frame edge and the second frame edge, and is also within the first substrate layer edge and the second substrate layer edge.

In one example, the dicing lane is equidistant between the first frame edge and the second frame edge. In one example, the dicing lane is equidistant between the first substrate layer edge and the second substrate layer edge. In one example, the frame defines the dicing lane to provide that the front width is less than the back width. In one example, the frame is a metal frame or a polymer frame. In one example, a lithographic process is used for depositing the frame in the wafer. In one example, the lithographic process is one of the following: a photolithography process, an optical lithography process, an ultraviolet (UV) lithography process, or an X-ray lithography process.

In one example, the frame is a metal frame of multiple layers. In one example, the metal frame includes one or more of the following materials: aluminum (Al), copper (Cu), nickel (Ni), tungsten (W), or aluminum copper alloy (Al Cu). In one example, the depositing the frame in the wafer is performed using chemical vapor deposition (CVD) or physical vapor deposition (PVD).

In one example, the method further includes depositing a trim layer on the wafer. In one example, the trim layer includes a silicon nitride (Si N) substrate. In one example, the method further includes exposing the trim layer by etching in an electrical contact region of the wafer. In one example, the electrical contact region is the frame.

In one example, the method further includes covering one or more portions of the frame with a solder layer. In one example, the one or more portions are solderable portions of the frame and one or more input/output (I/O) terminals on the wafer. In one example, the solder layer connects the frame and the one or more input/output (I/O) terminals with a counterpart in one of the following: a universal laminate lid package (ULLP), a universal stacked die package (USDP) or a universal interposer lid package (UILP).

Another aspect of the disclosure provides a wafer for dicing into a first device and a second device, the wafer including a substrate layer, wherein the substrate layer comprises a first substrate layer edge associated with the first device and a second substrate layer edge associated with the second device; a passivation layer adjacent to the substrate layer; a frame abutting the passivation layer, wherein the frame comprises a first frame edge associated with the first device and a second frame edge associated with the second device; and wherein a front width is a first distance between the first frame edge and the second frame edge, and a back width is a second distance between the first substrate layer edge and the second substrate layer edge; and wherein the front width is less than the back width.

In one example, the passivation layer includes a piezoelectric layer with one or more electrodes. In one example, the frame defines a dicing lane to provide that the front width is less than the back width. In one example, the frame is a metal frame or a polymer frame. In one example, a lithographic process is used for depositing the frame in the wafer.

In one example, the wafer further includes a solder layer, wherein the solder layer covers one or more portions of the frame. In one example, the one or more portions are solderable portions of the frame and one or more input/output (I/O) terminals on the wafer. In one example, the solder layer connects the frame and the one or more input/output (I/O) terminals with a counterpart in one of the following: a universal laminate lid package (ULLP), a universal stacked die package (USDP) or a universal interposer lid package (UILP).

Another aspect of the disclosure provides a wafer for dicing into a first device and a second device, the wafer including a substrate layer, wherein the substrate layer comprises a first substrate layer edge associated with the first device and a second substrate layer edge associated with the second device; a piezoelectric layer adjacent to the substrate layer; a metal frame abutting the piezoelectric layer, wherein the metal frame comprises a first frame edge associated with the first device and a second frame edge associated with the second device; and wherein a front width is a first distance between the first frame edge and the second frame edge, and a back width is a second distance between the first substrate layer edge and the second substrate layer edge; and wherein the front width is less than the back width; and a solder layer, wherein the solder layer covers a portion of the metal frame. In one example, the solder layer connects the metal frame and one or more input/output (I/O) terminals of the wafer with a counterpart in one of the following: a universal laminate lid package (ULLP), a universal stacked die package (USDP) or a universal interposer lid package (UILP).

Another aspect of the disclosure provides a computer-readable medium storing computer executable code, operable on a device including at least one processor and at least one memory coupled to the at least one processor, wherein the at least one processor is configured to implement a wafer for dicing into a first device and a second device, the computer executable code including instructions for causing a computer to form a substrate layer in the wafer, wherein the substrate layer comprises a first substrate layer edge associated with the first device and a second substrate layer edge associated with the second device; instructions for causing the computer to deposit a passivation layer onto the substrate layer; and instructions for causing the computer to deposit a frame in the wafer, wherein the frame abuts the passivation layer and wherein the frame comprises a first frame edge associated with the first device and a second frame edge associated with the second device; and wherein a front width is a first distance between the first frame edge and the second frame edge, and a back width is a second distance between the first substrate layer edge and the second substrate layer edge; and wherein the front width is less than the back width.

In one example, the computer-readable medium further includes instructions for causing the computer to dice the wafer along a dicing lane to form the first device and the second device, wherein the dicing lane is within the first frame edge and the second frame edge, and is also within the first substrate layer edge and the second substrate layer edge.

These and other aspects of the present disclosure will become more fully understood upon a review of the detailed description, which follows. Other aspects, features, and implementations of the present disclosure will become apparent to those of ordinary skill in the art, upon reviewing the following description of specific, exemplary implementations of the present invention in conjunction with the accompanying figures. While features of the present invention may be discussed relative to certain implementations and figures below, all implementations of the present invention can include one or more of the advantageous features discussed herein. In other words, while one or more implementations may be discussed as having certain advantageous features, one or more of such features may also be used in accordance with the various implementations of the invention discussed herein. In similar fashion, while exemplary implementations may be discussed below as device, system, or method implementations it should be understood that such exemplary implementations can be implemented in various devices, systems, and methods.

### BRIEF DESCRIPTION OF THE DRAWINGS

FIG. 1 illustrates an example of a passivation layer above a substrate layer of a wafer.

FIG. 2 illustrates an example of a passivation layer above a substrate layer with a metal layer on a wafer.

FIG. 3 illustrates an example wafer after dicing.

FIG. 4 illustrates an example flow diagram for wafer dicing with a frame.

FIG. 5 illustrates an example wafer with example features of singulated devices from the wafer obtained by wafer dicing through a metal frame.

FIG. 6 illustrates an example device fabricated by wafer dicing through a metal frame.

FIG. 7 illustrates an example wafer after device singulation obtained by dicing with a large dicing lane.

FIG. 8 illustrates an example wafer after device singulation obtained by dicing through a metal frame.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

Wafers may be used for production of devices, such as semiconductor devices. Wafers may include a variety of materials such as semiconductor, glass, piezoelectric, composite, etc. In one example, selection of material for the wafer may depend on an application.

In one example, current wafer production techniques, for example, blade or plasma dicing, laser ablation or etching, etc., remove material from the wafer which results in a loss of valuable wafer space and therefore a limit to the quantity of devices per wafer. For example, other wafer production techniques such as stealth dicing or other cleaving methods do not remove material from the wafer. However, these and other wafer production techniques may be limited by some technological constraint such as laser alignment, lithographic mask alignment, dicing blade alignment. In addition, current wafer production techniques may be limited by required exclusion zone widths on two sides of lateral grooves since potential chipping or breakage of wafer material should not degrade device functionality. The present disclosure minimizes spacing between adjacent devices on a wafer. As a result, the quantity of devices per wafer may increase.

A conventional blade dicing process from one perimeter of the device has an area loss due to a wider kerf width and a wide exclusion zone width on two sides of the dicing lane. To mitigate the area loss, the present disclosure provides for wafer dicing with a frame.

In one example, a frame may be placed on a perimeter of a device (e.g., chip or die) on a wafer. The wafer may include a substrate material such as semiconductor, glass, piezoelectric, composite, etc. For example, the frame may be a metal frame, a polymer frame, etc. In one example, the perimeter of the device may be a back side or a front side of the device. For example, a minimum distance between adjacent frames may be used. In one example, wafer dicing may be performed using an etch process (e.g., back-side etch or front-side etch), an ablation process (e.g., back-side ablation or front side ablation) or a blade dicing approach process (e.g., a back-side blade dicing).

In one example, placement of a frame onto a wafer on a first perimeter (e.g., front side) of a device may prevent over-etching of the substrate material on a second perimeter (e.g., back side) of the device when the etch process is used. In one example, the frame on the first perimeter (e.g., front side) may prevent chipping of the substrate material on the first perimeter when the blade dicing process is used on the second perimeter (e.g., back side). For example, the frame on the first perimeter reduces a device area and enables a reduction of the dicing lane below a threshold distance. In one example, the threshold distance is 10 micrometers. In one example, the frame on the first perimeter results in smaller device layouts and enables production of lower cost devices.

In one example, placement of a frame onto a wafer may be done on both a first perimeter and a second perimeter of a device. In one example, dicing of the wafer may be performed on either the first perimeter or the second perimeter of the device. In one example, dicing on a back side may be performed to maximize area utilization.

In one example, if an etch process (e.g., plasma dicing) is used to dice a wafer on a first perimeter without a frame on a first perimeter and with a frame on a second perimeter, the frame may be added to the first perimeter subsequent to dicing the device, for example, to enable three-dimensional (3D) stacking.

In one example, the frame may be used as a ground reference and may be connected to an electrode. Connecting to an electrode may, for example, allow the use of less individual input/output connections (e.g., bumps, conducting pillars, etc.) and thereby allow additional device shrink.

In one example, the frame may be a metal frame and may be solderable. Alternatively, the frame may be a polymer frame, which may be larger than the metal frame, and the frame may include a ground reference using an extra ground pin (e.g., under-bump metallization (UBM), microbump, etc.). In one example, the polymer frame may be created using a cured (e.g., hardened) polymer to avoid chipping. In addition, a second polymer frame may be required to create a bond frame between the device and other structures (e.g., another device, interposer, laminate, etc.).

In one example, placement of a frame onto a wafer may be used for acoustic resonators, for example, based on a hermetic substrate and covered by a hermetic material (e.g., dielectrics such as silicon nitride). In one example, an exposed outer perimeter edge may be unprotected from a corrosive substance (e.g., water, salt solution, etc.). In one example, the frame may wrap around an outer perimeter edge to cover all included layers and to create a hermetic seal for the included layers.

In one example, an under-bump metallization (UBM) may be implemented in-situ for other input/output interfaces inside the frame on a side where the frame is created. For example, as the frame may self-align to its counterpart during soldering, a size of the UBM may be reduced to a minimum size determined by its material conductivity and a maximum allowable ohmic loss. In one example, due to self-alignment, no extra area may be required for alignment inaccuracy which allows a small pitch (i.e., <100 micrometers pitch) and a high input/output density.

In one example, after placement of a frame onto a wafer, a hollow space for a resonator may be created in the device package. Resonators may be placed with a flexible arrangement of input/output terminals or contacts that serve as a heat sink. For example, mechanical posts may be created to mitigate moldability with high pressure. In one example, over moldability refers to a physical condition where a large pressure from molding causes deformation in a wafer.

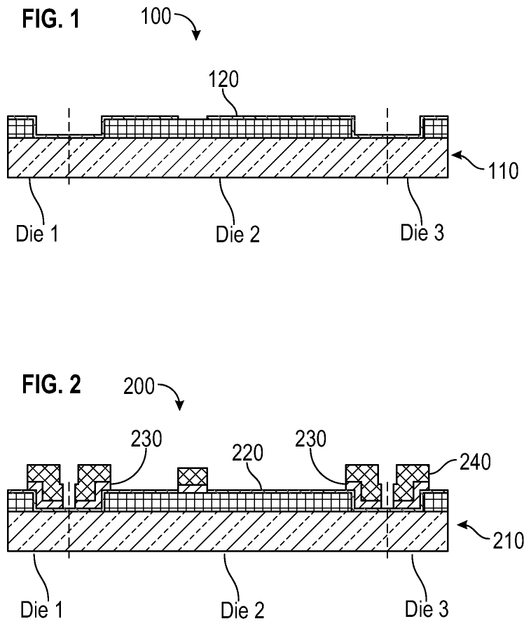

FIG. 1 illustrates an example 100 of a passivation layer above a substrate layer of a wafer. In one example, the passivation layer 120 may include openings to the substrate layer 110 for input/output (I/O) connections. In one example, the passivation layer may be used to protect functional structures on the wafer. In one example, the passivation layer includes a piezoelectric layer (a.k.a. piezo layer) with one or more electrodes.

FIG. 2 illustrates an example 200 of a passivation layer 220 above a substrate layer 210 with a metal layer 230 on a wafer. In one example, the metal layer 230 is a metal frame. In one example, the metal layer 230 may be formed using a lithographic process. In one example, the metal layer 230 may include one or more layers. In one example, the metal layer may include one or more of the following materials: aluminum (Al), copper (Cu), nickel (Ni), tungsten (W), and/or aluminum copper alloy (Al Cu), etc. In one example, the metal layer 230 may include a solder layer 240. In one example, the solder layer 240 may be a solderable metal layer.

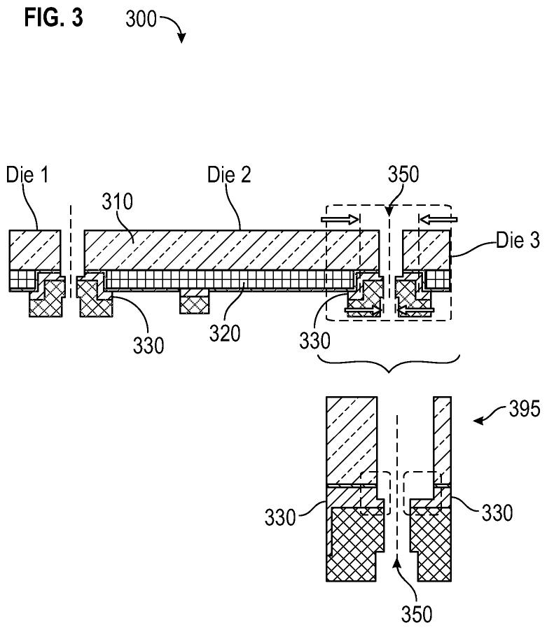

FIG. 3 illustrates an example wafer 300 after dicing. Shown in FIG. 3 on the wafer 300 is a passivation layer 320 above a substrate layer 310 with a metal layer 330. In one example, wafer dicing may be characterized to as “after device singulation”. In one example, the wafer dicing is performed on a dicing lane 350. FIG. 3 shows an expanded view 395 of a portion of the wafer 300 with the dicing lane 350. In one example, the dicing lane 350 is defined by a lithographically structured metal on the metal layer 330. In one example, the width of the dicing lane 350 is less than a sum of tool alignment accuracy width, kerf width and exclusion zone width. In one example, wafer dicing may include the front side of the wafer until the metal layer 330 is cut. In one example, the kerf width is a distance between two substrate layers. In one example, the exclusion zone width is a distance which cannot be used for any functionality due to material loss such as chipping.

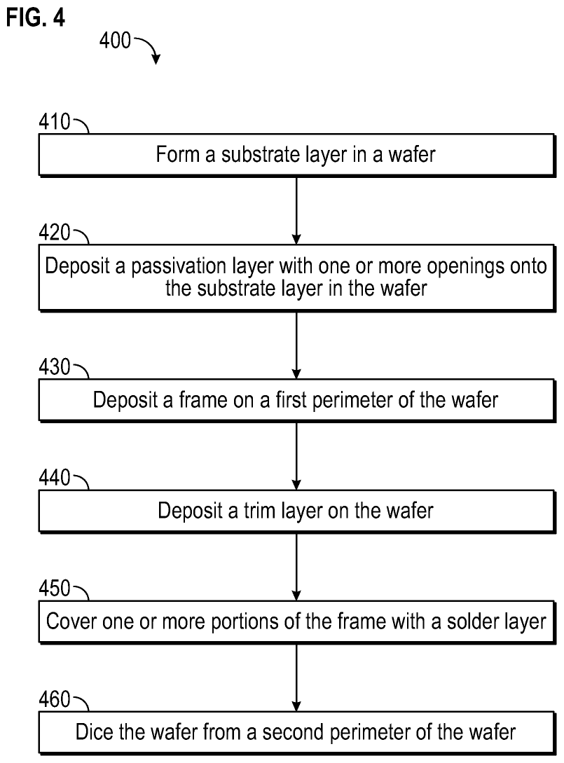

FIG. 4 illustrates an example flow diagram 400 for wafer dicing with a frame. In block 410, form a substrate layer in a wafer. In one example, the substrate layer may be a semiconductor, glass, piezoelectric, or composite material.

In block 420, deposit a passivation layer with one or more openings onto the substrate layer in the wafer. In one example, the one or more openings are used for input/output (I/O) connections. In one example, the passivation layer includes a piezoelectric layer with one or more electrodes.

In block 430, deposit a frame on a first perimeter of the wafer. In one example, the first perimeter is a front side of the wafer. In one example, the frame is a metal frame. In another example, the frame is a polymer frame. In one example, the frame defines a dicing lane having a width greater on a back side of the wafer relative to the front side of the wafer. In one example, the depositing is performed using a lithographic process. For example, the lithographic process may be photolithography, optical lithography, ultraviolet (UV) lithography, X-ray lithography, etc. For example, the depositing may be performed on a structured resist to use with a lift off process. For example, the depositing may be performed directly on an underlying RF structure to use with back-etching.

In one example, the metal frame may include one or more layers. In one example, the metal frame may include aluminum (Al), copper (Cu), nickel (Ni), tungsten (W), aluminum copper alloy (Al Cu), etc. In one example, the depositing is performed using chemical vapor deposition (CVD) or physical vapor deposition (PVD). In one example, if the metal frame includes a non-solderable layer (e.g., Al Cu alloy), a subsequent process may be employed to form an under-bump metallization (UBM) or a solder reservoir. In one example, the subsequent process may be employed to form a microbump.

In one example, if the metal frame includes a solder layer, another structure may form a solder reservoir. In one example, the another structure may be another die, an interposer, a laminate I/O, or a frame structure, etc. In another example, the depositing of the frame may be on both a first perimeter (e.g., front side) and a second perimeter (e.g., back side) of the wafer.

In block 440, deposit a trim layer on the wafer. In one example, the trim layer includes a silicon nitride (Si N) substrate. In one example, the trim layer may be exposed by etching in an electrical contact region to allow an electrical connection to, for example, an I/O connection. In one example, the electrical contact region may be the metal frame, the under-bump metallization (UBM), etc. For example, the etching may terminate on a solderable metal layer. For example, all trim steps may be performed with the depositing the trim layer.

In one example, the trim layer may be a thin layer of silicon nitride adjacent to the passivation layer or the piezoelectric layer. For example, the silicon nitride layer may be selectively thinned to adjust a thickness and local mass. For example, the selective thinning may be used to tune a radio frequency (RF) filter which is sensitive to its local mass. In one example, the depositing the trim layer may be repeated multiple times until a targeted thickness and local mass are achieved.

In block 450, cover one or more portions of the frame with a solder layer. In one example the one or more portions are solderable portions of the metal frame and input/output (I/O) terminals. In one example, the solder layer may connect the metal frame and input/output (I/O) terminals with a counterpart in a universal laminate lid package (ULLP), a universal stacked die package (USDP) or a universal interposer lid package (UILP).

In block 460, dice the wafer from a second perimeter of the wafer. In one example, the second perimeter is a back side of the wafer. In one example, the wafer dicing is performed on a dicing lane. In one example, the dicing lane has a width greater on the back side of the wafer than its width on the front side of the wafer. In one example, the dicing lane is defined by a lithographically structured metal on the metal frame. In one example, the width of the dicing lane is less than a sum of tool alignment accuracy width, kerf width and exclusion zone width. In one example, wafer dicing may include the front side of the wafer until the metal frame is cut. In one example, wafer dicing may be performed using an etch process, an ablation process or a blade dicing approach process. Examples of the etch process may include a back-side etch or a front-side etch. Examples of the ablation process may include a back-side ablation or a front side ablation. Examples of the blade dicing approach process may include a back-side blade dicing.

In one example, after wafer dicing through the substrate layer, another process may be used to etch through the substrate layer to open remaining layers. In one example, the another process may include laser ablation or laser cutting. In one example, the cutting of the metal frame singulates (i.e., dices) a plurality of devices on the wafer.

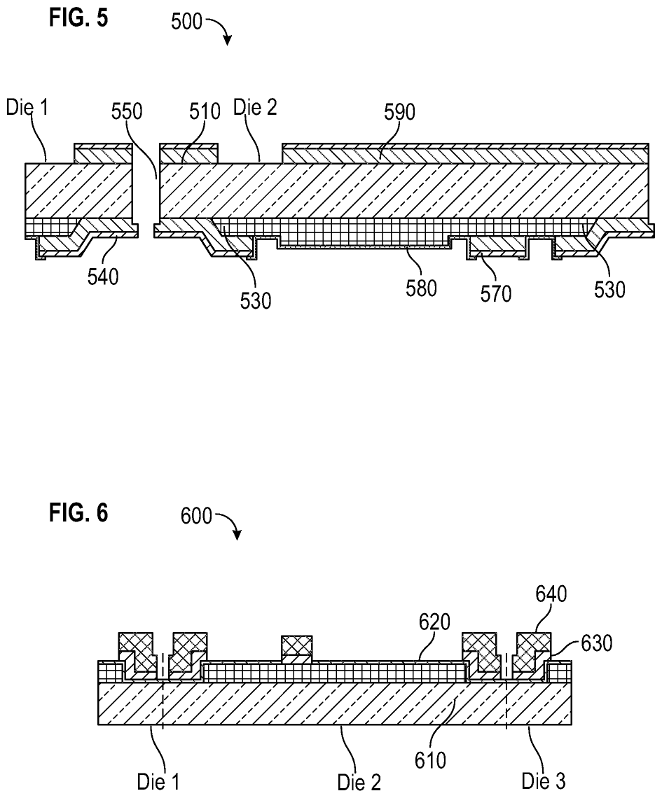

FIG. 5 illustrates an example wafer 500 with example features of singulated devices from the wafer obtained by wafer dicing through a metal frame 530. Although the example in FIG. 5 discloses a metal frame, one skilled in the art would understand that other types of frames may be used within the spirit and scope of the present disclosure. In one option, metal frames may be used on both sides (i.e., front side and back side) of the wafer 500. In one example, the metal frame 530 defines a dicing lane 550 between adjacent devices on the wafer 500. In one example, a kerf width or etching groove width is greater than a distance between adjacent metal frames (e.g., dicing lane 550). FIG. 5 also shows a substrate layer 510. In one example, the metal frame 530 on the back side may be removed in the position of the dicing lane 550 (i.e., the metal frame 530 on the back side may not cover the dicing lane 550.)

In one example, the wafer 500 includes a solder layer 540 that covers the metal frame 530. The solder layer 540 is an optional feature. In one example, the metal frame 530 defines a dicing lane 550 having a width greater on a back side of the wafer relative to the front side of the wafer. In one example, the wafer 500 includes a non-solderable layer 580 as shown in FIG. 5. In one example, the wafer 500 may include a metallization layer 570 which may serve as input/output (I/O) terminals. In one example, a top side 590 of the wafer 500 may serve as a heat sink for the wafer.

FIG. 6 illustrates an example device 600 fabricated by wafer dicing through a metal frame 630. Shown are a substrate layer 610, a passivation layer 620, a metal frame 630 and a solder layer 640. Although the example in FIG. 6 discloses a metal frame, one skilled in the art would understand that other types of frames may be used within the spirit and scope of the present disclosure. In one example, the substrate layer 610 includes one or more of the following materials: semiconductor, glass, piezoelectric and/or composite material. In one example, the passivation layer 620 includes a piezoelectric layer with one or more electrodes. In one example, the metal frame 630 may be a metal layer, such as aluminum (Al), copper (Cu), nickel (Ni), tungsten (W), and/or aluminum copper alloy (Al Cu), etc.

In one example, singulated devices from a wafer obtained by wafer dicing through a metal frame facilitates input/output (I/O) terminals with an ultra low pitch and a lower device package height. In one example, wafer dicing through a metal frame allows more flexibility for an arrangement and shape of various circuits, such as a radio frequency (RF) resonator. In one example, wafer dicing through a metal frame may yield more devices per wafer which reduces front end cost and total fabrication cost of multiple devices from a single wafer. In one example, singulated devices from a wafer obtained by wafer dicing through a metal frame facilitates bonding or soldering of microbumps and for bonding a plurality of devices (e.g., stacks of devices).

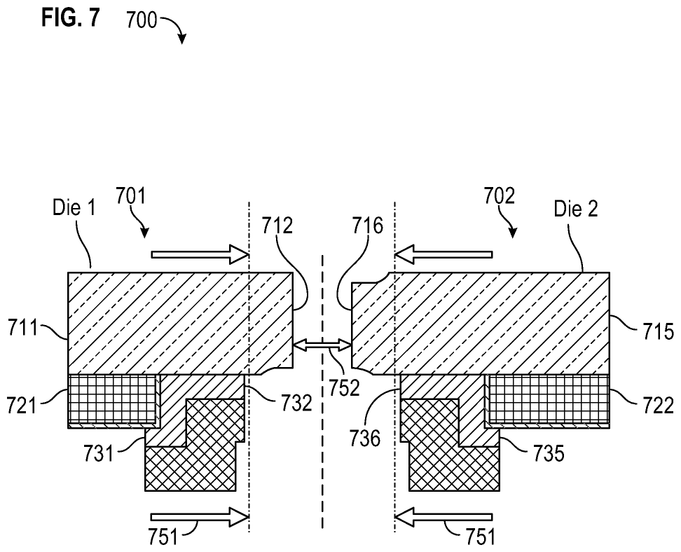

FIG. 7 illustrates an example wafer 700 after device singulation obtained by dicing with a large dicing lane. In one example, the wafer 700 includes a metal frame 730 (not marked in FIG. 7) which includes a first metal layer 731 and a second metal layer 735. A first device 701 (which includes “die 1”) includes a first substrate layer 711, a first functional layer 721 and the first metal layer 731. A second device 702 includes a second substrate layer 715, a second functional layer 722 and the second metal layer 735. In one example, the first functional layer 721 and the second functional layer 722 may include a passivation layer to protect the first functional layer 721 and the second functional layer 722. In one example, the first substrate layer 711 and the second substrate layer 715 may include silicon, other semiconductor materials, or piezoelectric materials.

In one example, a front width 751 between an edge 732 of the first metal layer 731 and an edge 736 of the second metal layer 735 is greater than a back width 752 between an edge 712 of the first substrate layer 711 and an edge 716 of the second substrate layer 715. For example, a distance (i.e., front width 751) between the first metal layer 731 and the second metal layer 735 is greater than a distance (i.e., back width 752) between the first substrate layer 711 and the second substrate layer 715. In one example, a dicing lane width is governed by a sum of a kerf width (i.e., dicing trench width to singulate devices), a tool misalignment width and an exclusion zone width (e.g., width allowance for chipping, over-etching or recast). In one example, the dicing lane width may be equal to the front width. For example, the dicing lane width may be greater than 30 micrometers for plasma dicing, greater than 40 micrometers for laser dicing and greater than 50 micrometers for blade dicing. In one example, a device may have a variable width of approximately 30 micrometers which may force a large dicing lane width.

In one example, the first metal layer 731 and the second metal layer 735 may be used for die bonding. In one example, the first metal layer 731 and the second metal layer 735 may include multiple layers. In one example, the first substrate layer 711 and the second substrate layer 715 may include bulk substrate material, such as silicon (Si) or piezo material).

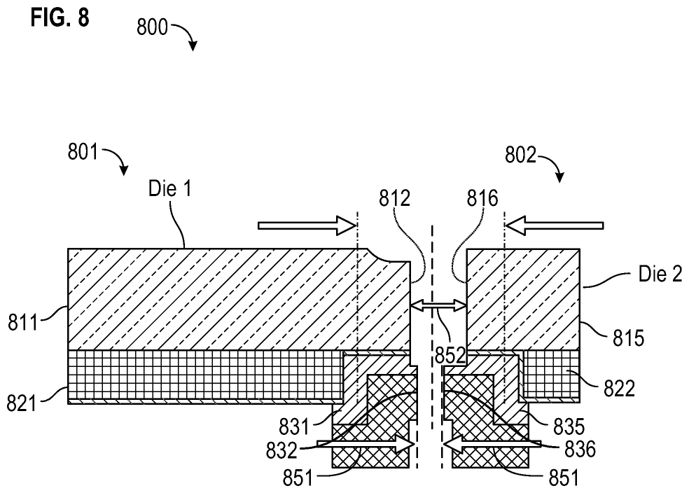

FIG. 8 illustrates an example wafer 800 after device singulation obtained by dicing through a metal frame 830. In one example, the metal frame 830 (not marked in FIG. 8) which includes a first metal layer 831 and a second metal layer 835.

In one example, the metal frame 830 defines a dicing lane width. A first device 801 includes a first substrate layer 811, a first functional layer 821 and a first metal layer 831. A second device 802 includes a second substrate layer 815, a second functional layer 822 and a second metal layer 835. In one example, the first functional layer 821 and the second functional layer 822 may include a passivation layer to protect the first functional layer 821 and the second functional layer 822. In one example, the first substrate layer 811 and the second substrate layer 815 may include silicon, other semiconductor materials, and/or piezoelectric materials.

In one example, a front width 851 between an edge 832 of the first metal layer 831 and an edge 836 of the second metal layer 835 is less than a back width 852 between an edge 812 of the first substrate layer 811 and an edge 816 of the second substrate layer 815. For example, a distance (i.e., front width 851) between the first metal layer 831 and the second metal layer 835 is less than a distance (i.e., back width 852) between the first substrate layer 811 and the second substrate layer 815. In one example, the dicing lane width may be equal to the front width. In one example, the dicing lane width may be less than 10 micrometers, independent of dicing technique.

In one example, the dicing lane width may be smaller than conventional examples. In one example, a device may have a variable width of approximately 2 micrometers due to a lithographically defined metal layer. In one example, the lithographically defined metal layer allows a small dicing lane width and a smaller spacing of devices which facilitates a larger quantity of devices per wafer.

In one aspect, one or more of the steps for wafer dicing with a frame in FIG. 4 may be executed by one or more processors which may include hardware, software, firmware, etc. In one aspect, one or more of the steps in FIG. 4 may be executed by one or more processors which may include hardware, software, firmware, etc. The one or more processors, for example, may be used to execute software or firmware needed to perform the steps in the flow diagram of FIG. 4. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium may reside in the processing system, external to the processing system, or distributed across multiple entities including the processing system. The computer-readable medium may be embodied in a computer program product. By way of example, a computer program product may include a computer-readable medium in packaging materials. The computer-readable medium may include software or firmware for wafer dicing with a frame. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

What is claimed is:

1. A method for dicing a wafer into a first device and a second device through a metal frame, the method comprising:
forming a substrate layer in the wafer, wherein the substrate layer comprises a first substrate layer edge associated with the first device and a second substrate layer edge associated with the second device;
depositing a passivation layer onto the substrate layer; and
depositing a frame in the wafer, wherein the frame abuts the passivation layer and wherein the frame comprises a first frame edge associated with the first device and a second frame edge associated with the second device;
and wherein a front width is a first distance between the first frame edge and the second frame edge, and a back width is a second distance between the first substrate layer edge and the second substrate layer edge;
and wherein the front width is less than the back width.

2. The method of claim 1, further comprising dicing the wafer along a dicing lane to form the first device and the second device, wherein the dicing lane is within the first frame edge and the second frame edge, and is also within the first substrate layer edge and the second substrate layer edge.

3. The method of claim 2, wherein the dicing lane is equidistant between the first frame edge and the second frame edge.

4. The method of claim 2, wherein the dicing lane is equidistant between the first substrate layer edge and the second substrate layer edge.

5. The method of claim 2, wherein the frame defines the dicing lane to provide that the front width is less than the back width.

6. The method of claim 5, wherein the frame is a metal frame or a polymer frame.

7. The method of claim 5, wherein a lithographic process is used for depositing the frame in the wafer.

8. The method of claim 7, wherein the lithographic process is one of the following: a photolithography process, an optical lithography process, an ultraviolet (UV) lithography process, or an X-ray lithography process.

9. The method of claim 5, wherein the frame is a metal frame of multiple layers.

10. The method of claim 9, wherein the metal frame includes one or more of the following materials: aluminum (Al), copper (Cu), nickel (Ni), tungsten (W), or aluminum copper alloy (Al Cu).

11. The method of claim 10, wherein the depositing the frame in the wafer is performed using chemical vapor deposition (CVD) or physical vapor deposition (PVD).

12. The method of claim 2, further comprising depositing a trim layer on the wafer.

13. The method of claim 12, wherein the trim layer includes a silicon nitride (Si N) substrate.

14. The method of claim 13, further comprising exposing the trim layer by etching in an electrical contact region of the wafer.

15. The method of claim 14, wherein the electrical contact region is the frame.

16. The method of claim 2, further comprising covering one or more portions of the frame with a solder layer.

17. The method of claim 16, wherein the one or more portions are solderable portions of the frame and one or more input/output (I/O) terminals on the wafer.

18. The method of claim 17, wherein the solder layer connects the frame and the one or more input/output (I/O) terminals with a counterpart in one of the following: a universal laminate lid package (ULLP), a universal stacked die package (USDP) or a universal interposer lid package (UILP).

19. A wafer for dicing into a first device and a second device, the wafer comprising:
a substrate layer, wherein the substrate layer comprises a first substrate layer edge associated with the first device and a second substrate layer edge associated with the second device;
a passivation layer adjacent to the substrate layer;
a frame abutting the passivation layer, wherein the frame comprises a first frame edge associated with the first device and a second frame edge associated with the second device;
and wherein a front width is a first distance between the first frame edge and the second frame edge, and a back width is a second distance between the first substrate layer edge and the second substrate layer edge;
and wherein the front width is less than the back width.

20. The wafer of claim 19, wherein the passivation layer includes a piezoelectric layer with one or more electrodes.

21. The wafer of claim 20, wherein the frame defines a dicing lane to provide that the front width is less than the back width.

22. The wafer of claim 21, wherein the frame is a metal frame or a polymer frame.

23. The wafer of claim 22, wherein a lithographic process is used for depositing the frame in the wafer.

24. The wafer of claim 23, further comprising a solder layer, wherein the solder layer covers one or more portions of the frame.

25. The wafer of claim 24, wherein the one or more portions are solderable portions of the frame and one or more input/output (I/O) terminals on the wafer.

26. The wafer of claim 25, wherein the solder layer connects the frame and the one or more input/output (I/O) terminals with a counterpart in one of the following: a universal laminate lid package (ULLP), a universal stacked die package (USDP) or a universal interposer lid package (UILP).

27. A wafer for dicing into a first device and a second device, the wafer comprising:
a substrate layer, wherein the substrate layer comprises a first substrate layer edge associated with the first device and a second substrate layer edge associated with the second device;
a piezoelectric layer adjacent to the substrate layer;
a metal frame abutting the piezoelectric layer, wherein the metal frame comprises a first frame edge associated with the first device and a second frame edge associated with the second device;
and wherein a front width is a first distance between the first frame edge and the second frame edge, and a back width is a second distance between the first substrate layer edge and the second substrate layer edge;
and wherein the front width is less than the back width; and
a solder layer, wherein the solder layer covers a portion of the metal frame.

28. The wafer of claim 27, wherein the solder layer connects the metal frame and one or more input/output (I/O) terminals of the wafer with a counterpart in one of the following: a universal laminate lid package (ULLP), a universal stacked die package (USDP) or a universal interposer lid package (UILP).

29. A computer-readable medium storing computer executable code, operable on a device comprising at least one processor and at least one memory coupled to the at least one processor, wherein the at least one processor is configured to implement a wafer for dicing into a first device and a second device, the computer executable code comprising:
instructions for causing a computer to form a substrate layer in the wafer, wherein the substrate layer comprises a first substrate layer edge associated with the first device and a second substrate layer edge associated with the second device;
instructions for causing the computer to deposit a passivation layer onto the substrate layer; and
instructions for causing the computer to deposit a frame in the wafer, wherein the frame abuts the passivation layer and wherein the frame comprises a first frame edge associated with the first device and a second frame edge associated with the second device;
and wherein a front width is a first distance between the first frame edge and the second frame edge, and a back width is a second distance between the first substrate layer edge and the second substrate layer edge;
and wherein the front width is less than the back width.

30. The computer-readable medium of claim 29, further comprising instructions for causing the computer to dice the wafer along a dicing lane to form the first device and the second device, wherein the dicing lane is within the first frame edge and the second frame edge, and is also within the first substrate layer edge and the second substrate layer edge.
